(19) United States
(12) Patent Application Publication
(10) Pub. No.: US 2025/0328265 A1
(43) Pub. Date: Oct. 23, 2025

(54) METHOD AND DEVICE FOR MULTI-DIMENSIONAL CLOCK-GATING AND ADDRESS DECODING FOR REGISTER FILES AND RANDOM-ACCESS MEMORIES

(71) Applicant: Samsung Electronics Co., Ltd., Gyeonggi-do (KR)

(72) Inventors: Jang Dae KIM, San Jose, CA (US); Hoyeol CHO, Campbell, CA (US)

(21) Appl. No.: 19/052,950

(22) Filed: Feb. 13, 2025

Related U.S. Application Data
(60) Provisional application No. 63/636,303, filed on Apr. 19, 2024.

(51) Int. Cl. G06F 3/06; G06F 1/04

(52) U.S. Cl. CPC G06F 3/0625; G06F 1/04; G06F 3/0659; G06F 3/0673

(57) ABSTRACT

A method and device are provided in which at least a first portion of a write address bus comprising a write address from a write command is received at a first decoder of a memory device, wherein the memory device comprises a set of memory cell rows corresponding to a subset of write addresses from write commands. A first clock signal is received at a first primary integrated clock gating (ICG) cell of the memory device. The first primary ICG cell is configured to provide a first gated clock signal to a first subcircuit of the memory device, including a first non-empty proper subset of the memory cell rows, wherein the first non-empty proper subset includes a plurality of memory cell rows. The first decoder enables or disables the first primary ICG cell, when the write address is in the subset of the write addresses, based on whether the write address corresponds to any memory cell row in the first non-empty proper subset of the memory cell rows, disabling the first primary ICG cell when the write address corresponds to a memory cell row in the set of the memory cell rows but not in the first non-empty proper subset.

### CROSS-REFERENCE TO RELATED APPLICATION

This application claims the priority benefit under 35 U.S.C. § 119 (c) of U.S. Provisional Application No. 63/636,303, filed on Apr. 19, 2024, the disclosure of which is incorporated by reference in its entirety as if fully set forth herein.

### TECHNICAL FIELD

The disclosure generally relates to data storage in register files or random-access memories (RAMs). More particularly, the subject matter disclosed herein relates to improvements to clock-gating and address decoding for register files and RAMs.

### SUMMARY

Clock gating is a widely utilized technique for reducing dynamic power consumption in digital circuits, particularly in register files and RAMs. By selectively enabling or disabling clock signals based on specific operational requirements, clock gating minimizes unnecessary toggling of circuits, thereby conserving power. This technique is especially critical in modern integrated circuits (ICs), where power efficiency is a significant design constraint.

In register transfer language (RTL) designs, register files and RAMs are often implemented with fine-grain clock gating to achieve power savings. This may be accomplished using integrated clock-gating (ICG) cells on each memory row in a single dimension. These cells receive an input clock signal and selectively gate it to provide output gated-clock signals, passing a clock signal only to the memory rows addressed for write operations.

For smaller memory sizes, this approach is effective, as the number of ICG cells is relatively low, and the power overhead associated with the ICG cells is minimal. However, as the number of rows in a memory array increases, the power consumption of the ICG cells themselves and the clock buffers inserted in a large fanout input clock tree become significant. Specifically, even when an ICG cell is not selected (and hence its output clock signal is disabled), it still consumes clock power. This issue is particularly pronounced during write access, where the gating mechanism involves activating one ICG cell corresponding to the write address, while the remaining ICG cells and the input clock tree still draw clock power. This leads to inefficiencies that scale with the size of the memory array.

Memory compiler-generated static RAMs (SRAMs) employ a different approach to address decoding and clock gating. SRAMs use a two-level address decoding scheme where address bits are divided into two groups for pre-decoding. The first pre-decoder combines the input clock signal with specific address bits using AND gates to generate gated clock signals. These pre-decoded gated clock signals are then processed by a main decoder, which combines them with the outputs of the other pre-decoder to generate the final gated clock signals for the memory rows. This two-dimensional clock gating approach forms an AND-tree structure, embedding clock gating within the two-level address decoding process and allowing efficient power management.

One issue with the above approach is that such techniques are inherently tied to the SRAM custom design flow and are not directly applicable to RTL-based designs. RTL-based clock-gating mechanisms cannot directly adopt the AND gate-based clock gating used in SRAMs due to glitches in the clock tree and timing issues inherent in RTL flows, leading to functional errors. As described above, the scalability of existing solutions is limited, as the overhead associated with maintaining a large number of ICG cells grows disproportionately with the size of the memory array.

To overcome these issues, systems and methods are described herein that add a mediate layer of ICG cells, in which each mediate ICG cell feeds a gated clock to a subset of the original leaf ICG cells, thereby forming an ICG tree of clock signals for multi-dimensional clock gating. Further, a pre-decoder may be provided for the mediate ICG cell layer, and a separate post-decoder may be provided for the original leaf ICG layer. The pre-decoder and post-decoder may be separate from the ICG cells, and each decoder may provide enable signals to the ICG cells in a corresponding ICG layer of the ICG-tree.

The above approaches improve on previous methods because multi-dimensional clock gating reduces a total clock power and eliminates clock buffers in one-dimensional fine-grain clock gating.

In an embodiment, a method is provided in which at least a first portion of a write address bus comprising a write address from a write command may be received at a first decoder of a memory device, wherein the memory device comprises a set of memory cell rows corresponding to a subset of write addresses from write commands. A first clock signal may be received at a first primary ICG cells of the memory device. The first primary ICG cell may be configured to provide a first gated clock signal to a first subcircuit of the memory device, including a first non-empty proper subset of the memory cell rows of the memory device, wherein the first non-empty proper subset includes a plurality of memory cell rows. The first decoder may enable or disable the first primary ICG cell, when the write address is in the subset of the write addresses, based on whether the write address corresponds to any first memory cell row in the first non-empty proper subset of the memory cell rows, disabling the first primary ICG cell when the write address corresponds to a memory cell row in the set of the memory cell rows but not in the first non-empty proper subset.

In an embodiment, a memory device comprising a set of memory cell rows corresponding to a subset of write addresses from write commands is provided that includes a first subcircuit including a first non-empty proper subset of the memory cell rows, wherein the first non-empty proper subset includes a plurality of memory cell rows. The memory device also includes a write address bus configured to receive a write address from a write command. The memory device further includes a first primary ICG cell configured to receive a first clock signal. The first primary ICG cell may be configured to provide a first gated clock signal to the first subcircuit. The memory device additionally includes a first decoder configured to receive at least a first portion of the write address bus, and to enable or disable the first primary ICG cell, when the write address is in the subset of the write addresses, based on whether the write address corresponds to a first memory cell row in the first non-empty proper subset of memory cell rows, disabling the first primary ICG cell when the write address corresponds to a memory cell row in the set of the memory cell rows but not in the first non-empty proper subset.

In an embodiment, an electronic device is provided that includes a processor and a non-transitory computer readable storage medium storing instructions. When executed, the instructions may cause the processor to receive at least a first portion of a write address bus comprising a write address from a write command at a first decoder of a memory device, wherein the memory device comprises a set of memory cell rows corresponding to a subset of write addresses from write commands, and to receive a first clock signal at a first primary ICG cell of the memory device. The first primary ICG cell may be configured to provide a first gated clock signal to a first subcircuit including a first non-empty proper subset of the memory cell rows of the memory device, where the first non-empty proper subset includes a plurality of memory cell rows. The instructions may also cause the processor to enable or disable the first primary ICG cell, when the write address is in the subset of the write addresses, based on whether the write address corresponds to a first memory cell row of the first non-empty proper subset of memory cell rows, disabling the first primary ICG cell when the write address corresponds to a memory cell row in the set of the memory cell rows but not in the first non-empty proper subset.

### BRIEF DESCRIPTION OF THE DRAWING

In the following section, the aspects of the subject matter disclosed herein will be described with reference to exemplary embodiments illustrated in the figures, in which:

FIG. 1 is a diagram illustrating an electronic device, according to an embodiment;

FIG. 2 is a diagram illustrating fine-grain clock gating by an RTL memory;

FIG. 3 is a diagram illustrating two-dimensional clock gating by an RTL memory, according to an embodiment;

FIG. 4 is a diagram illustrating three-dimensional clock gating by an RTL memory, according to an embodiment;

FIG. 5 is a flowchart illustrating a clock-gating method for a memory device, according to an embodiment; and

FIG. 6 is a block diagram of an electronic device in a network environment, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

An electronic device, according to one embodiment, may be one of various types of electronic devices utilizing storage devices (e.g., memory devices). The electronic device may use any suitable storage standard, such as, for example, peripheral component interconnect express (PCIe), nonvolatile memory express (NVMe), NVMe-over-fabric (NVMcoF), advanced extensible interface (AXI), ultra path interconnect (UPI), ethernet, transmission control protocol/Internet protocol (TCP/IP), remote direct memory access (RDMA), RDMA over converged ethernet (ROCE), fibre channel (FC), infiniband (IB), serial advanced technology attachment (SATA), small computer systems interface (SCSI), serial attached SCSI (SAS), Internet wide-area RDMA protocol (iWARP), and/or the like, or any combination thereof. In some embodiments, an interconnect interface may be implemented with one or more memory semantic and/or memory coherent interfaces and/or protocols including one or more compute express link (CXL) protocols such as CXL.mem, CXL.io, and/or CXL.cache, Gen-Z, coherent accelerator processor interface (CAPI), cache coherent interconnect for accelerators (CCIX), and/or the like, or any combination thereof. Any of the memory devices may be implemented with one or more of any type of memory device interface including double data rate (DDR), DDR2, DDR3, DDR4, DDR5, low-power DDR (LPDDRX), open memory interface (OMI), Nvlink high bandwidth memory (HBM), HBM2, HBM3, and/or the like. The electronic devices may include, for example, a portable communication device (e.g., a smart phone), a computer, a portable multimedia device, a portable medical device, a camera, a wearable device, or a home appliance. However, an electronic device is not limited to those described above.

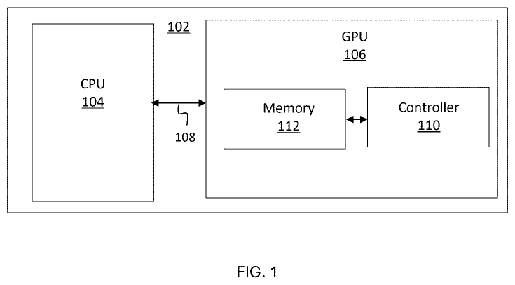

FIG. 1 is a diagram illustrating an electronic device, according to an embodiment. An electronic device (or user equipment (UE)) 102 may include multiple processing components that require efficient memory management. The electronic device 102 may include a central processing unit (CPU) 104 and an accelerator, such as a graphics processing unit (GPU) 106, interconnected by a memory bus 108. These processing units rely on memory subsystems that must balance high-speed data access with low power consumption. For example, the GPU 106 may include a controller 110 (e.g., computational engines and processors) and a memory 112.

RTL designs may be used in digital circuit design to describe the data flow and operations within a circuit. Clock gating is a technique used in digital circuit design to reduce power consumption by selectively disabling the clock signal to specific components of a circuit when they are not actively in use.

In RTL memory systems (without fine-grain clock-gating), all memory cells in a row (or entry) are clocked and updated simultaneously when a write enable signal is asserted. A multiplexer may be inferred on each memory cell of every row (e.g., entry). The multiplexer logic determines whether to update a memory cell with new data or its previous value, based on a received write address. An example of hardware description language (HDL) code for such an RTL memory is:

```
always @ (posedge clk) begin
  if (WrEn) begin
    Mem[WrAddr] <= WrData;
  end
end
```

This design may result in significant power consumption because the clock signal is distributed across all memory cells, regardless of the multiplexers' selections, when the write enable signal is asserted. Such inefficiency becomes critical in applications with large memory arrays or frequent write operations.

To address this limitation, fine-grain clock gating introduces ICG cells at the memory row level. These ICG cells (hereafter referred to as leaf ICG cells) enable clock signals only for specific memory rows corresponding to the write address when the write enable signal is asserted, thereby reducing power consumption. An example of HDL code for an RTL memory with fine-grain clock gating is:

```
always @ (posedge clk) begin
  if (WrEn) begin
    for (i = 0; i < NUM_ENTRIES; i = i + 1) begin
      if (WrAddr == i) begin
        Mem[i] <= WrData;
      end
    end
  end
end
```

While this approach is more energy efficient, further optimization may be achieved by explicitly integrating clock-gating logic into the RTL design. Leaf ICG cells may be explicitly disposed for each memory row. These cells may be selectively enabled by a write address decoder when the write enable signal is asserted. An example of HDL code for such an RTL memory is:

```
genvar icg_t1 ;
generate
  for (icg_t1=0; icg_t1<NUM_ENTRIES; icg_t1++) begin:u_icg_t1
    ‘POS_EDGE_ICG(u_icg, clk_gated[icg_t1], WrEn &&
(WrAddr==icg_t1), 1′b0, clk)
    always @ (posedge clk_gated[icg_t1]) begin
      Mem[icg_t1] <= WrData;
    end
  end
endgenerate
```

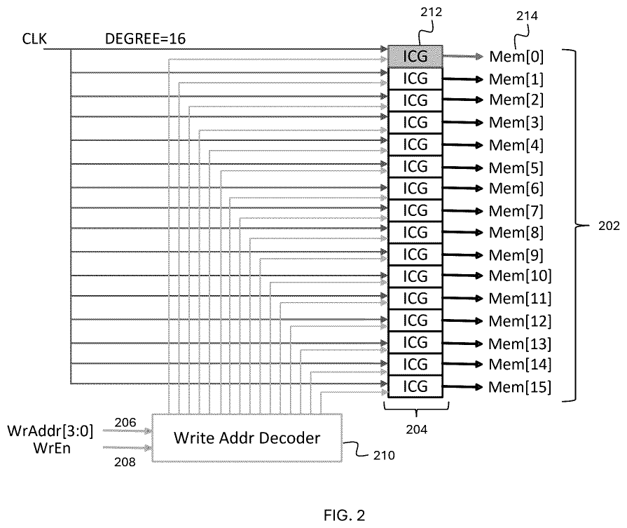

FIG. 2 is a diagram illustrating fine-grain clock gating by an RTL memory. A leaf ICG cell is disposed on each memory row and may be enabled by a write address decoder. Specifically, FIG. 2 illustrates an example with 16 rows of memory cells (i.e., 0-15) 202. The rows of memory cells 202 may have respective leaf ICG cells 204. Clock data or a clock signal (CLK) may be provided to each of the leaf ICG cells 204 (e.g., degree=16). A write address 206 and a write enable signal 208 may be provided to a write address decoder 210, and the write address decoder 210 may determine which leaf ICG cell to activate based on the write address 206 when the write enable signal 208 is asserted. For example, if the write address 206 may correspond to a first memory cell row (Mem[0]) 214, a first leaf ICG cell 212 generates a gated clock signal for the first memory cell row 214 when the write enable signal 208 is asserted. The remaining leaf ICG cells that are not selected by the write address 206 may remain disabled. This selective activation may conserve power by limiting clock activity to the targeted memory cell row. However, although the design significantly reduces output gated clock power, the input clock power to all leaf ICG cells (enabled or disabled) remains constant.

In accordance with an embodiment, two levels of ICG-based clock gating may be utilized with associated address decoding, similar to memory compiler generated SRAM, but for an RTL flow. Clock power of ICG cells may be reduced by a square-root of the number of original leaf ICG cells, using a small number (e.g., the square-root of original leaf ICG cells) of additional mediate ICG (mid-ICG or primary mediate ICG) cells. An example of HDL code for such an RTL memory is:

```
parameter CLOG2_DEGREE_ICG = WRADDR_WIDTH−WRADDR_WIDTH/2;
localparam NUM_MICG = 2 ** (WRADDR_WIDTH − CLOG2_DEGREE_ICG);
wire [NUM_MICG−1:0] clk_gated;
genvar micg_t1, mem_t1 ;
generate
  for (micg_t1=0; micg_t1<NUM_MICG; micg_t1++) begin:u_micg_t1
    ‘POS_EDGE_ICG(u_micg, clk_gated[icg_t1], WrEn &&
(WrAddr[WRADDR_WIDTH−1: CLOG2_DEGREE_ICG]==icg_t1), 1′b0, clk)
  end
  for (mem_t1=0; mem_t1<NUM_ENTRIES; mem_t1++) begin:u_mem_t1
    always @ (posedge clk_gated[$rtoi($ceil(mem_t1/(2**CLOG2_DEGREE_ICG)))])
begin
      if (WrAddr[WRADDR_WIDTH−1:0]==mem_t1) begin
        Mem[mem_t1] <= WrData;
      end
    end
  end
endgenerate
```

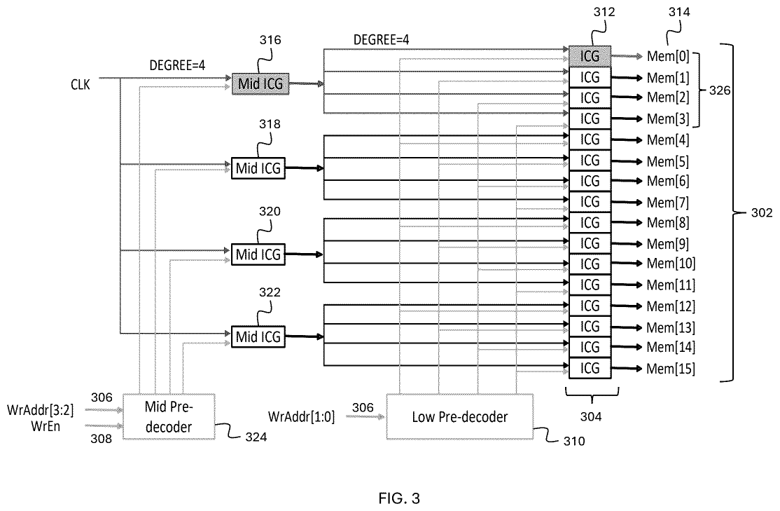

FIG. 3 is a diagram illustrating two-dimensional clock gating by an RTL memory, according to an embodiment. Similar to FIG. 2, a leaf ICG cell is disposed at each memory cell row (or addressable memory cell row) and may be enabled by a write address decoder. As an alternative, instead of leaf ICG cells, the rows of memory cells may embed a multiplexer in each memory cell. FIG. 3 also illustrates an example with 16 rows of memory cells (i.e., Mem[0-15]) 302. The rows of memory cells 302 may have respective leaf ICG cells 304. Mediate ICG (mid-ICG or primary ICG) cells may be provided for subsets of the leaf ICG cells 304. Specifically, a first mediate ICG cell 316 may be provided for a first subset of the leaf ICG cells 304 corresponding to a first group of four memory cell rows Mem[0-3] 326 (also referred to as a non-empty proper subset of multiple memory cell rows that are fewer than the total number of memory cell rows). A second mediate ICG cell 318 may be provided for a second subset of the leaf ICG cells 304 corresponding to a second group of four memory cell rows Mem[4-7]. A third mediate ICG cell 320 may be provided for a third subset of the leaf ICG cells 304 corresponding to a third group of four memory cell rows Mem[8-11]. A fourth mediate ICG cell 322 may be provided for a fourth subset of the leaf ICG cells 304 corresponding to a fourth group of four memory cell rows Mem[12-15].

Clock data or a clock signal (CLK) may be provided to each of the first four mediate ICG (mid ICG) cells 316, 318, 320, and 322. A write address 306 and a write enable signal 308 may be provided to a mid pre-decoder 324. The mid pre-decoder 324 may determine which mediate ICG cell to activate based on the write address 306. For example, if the write address 306 corresponds to the first memory cell row Mem[0], the first mediate ICG cell 316 may generate a gated clock signal to a subcircuit corresponding to the first subset of the leaf ICG cells 304 corresponding to the first group of four memory cell rows Mem[0-3] 326. The remaining mediate ICG cells 318, 320, and 322 that are not selected by the write address 306 may remain disabled, generating blocked clock signals.

The write address 306 may also be provided to a low pre-decoder 310. The low pre-decoder 310 may determine which leaf ICG cell among each subset of the leaf ICG cells 304 to activate based on the write address 306. For example, if the write address 306 corresponds to the first memory cell row Mem[0] 314, the first leaf ICG cell 312 generates a gated clock signal for the first memory cell row 314. The remaining leaf ICG cells in the first subset of the leaf ICG cells 304 that are not selected by the write address 306 may remain disabled, providing blocked clock signals. Other leaf ICG cells in the remaining subsets of the leaf ICG cells 304 provide blocked clock signals, irrespective of their enablement or disablement, as the clock signal is already blocked in their upstream mediate ICG cells. Alternatively, the low pre-decoder 310 may enable an embedded multiplexer row corresponding to the first memory cell row 314 among the first group of four memory cell rows Mem[0-3] 326 for the write address 306. The embedded multiplexer row may route memory input data to the memory cell row of the write address. Disabled remaining embedded multiplexer rows in the first subset of the memory cell rows may route corresponding memory cell rows to self-feed with their old stored values. The remaining multiplexer-embedded memory cell rows may receive blocked clock signals directly from their respective upstream mediate ICG cells that are disabled, so they remain unchanged.

This selective activation may conserve power by limiting output clock activity to the first mediate ICG cell 316 and the first leaf ICG cell 312. The input clock power for inactive mediate ICG and leaf ICG cells is limited to the second mediate ICG cell 318, the third mediate ICG cell 320, the fourth mediate ICG cell 322, and the three remaining ICG cells in the first subset of the leaf ICG cells 304. Accordingly, an input clock power is not provided to the second, third, and fourth subsets of the leaf ICG cells 304.

While FIG. 3 is shown with 16 leaf ICG cells and four mediate ICG cells, embodiments may not be limited to such a configuration. An optimum number of mediate ICG cells may be determined from a given set of leaf ICG cells. For a set of N leaf ICG cells and M mediate ICG cells, each mediate ICG cell feeds N/M downstream leaf ICG cells. Accordingly, M mediate ICG cells and N/M leaf ICG cells may be operating on a write-access. An optimum M may be a square-root of N (or an integer near a square-root of N). For example, if N is 9, M is 3. Thus, three mediate ICG cells and three leaf ICG cells may be operating (instead of nine ICG cells when performed without mediate ICG cells). In another example, if N is 7, the optimum M is 2 (provided that mediate ICG cells and ICG cells are the same). Thus, two mediate ICG cells are operating along with an average of 3.57 ICG leaf cells ((4 ICGs*4/7)+ (3 ICGs*3/7)). If M was instead 3, the three mediate ICG cells would operate along with an average of 2.71 leaf ICG cells ((3 ICGs*6/7)+ (1 ICG*(1/7)). In a further example, if N is 256, M is 16. Thus, 16 mediate ICG cells and 16 leaf ICG cells may be operating (instead of 256 ICG cells when performed without mediate ICG cells), resulting in a savings of 87.5% clock power in operating the ICG cells, and taking 6.25% more ICG area and associated leakage power for the 16 mediate ICG cells.

Accordingly, multiple (k−1) additional mediate ICG layers may be provided for k-dimensional clock gating. The original N leaf ICG cells may be re-arranged into k-dimensions for k-dimensional clock gating. The sum of the length on each axis may correspond to the number of additional mediate ICG cells and original leaf ICG cells operating on a write access. The sum of the length M on each axis may be smallest when M is a geometrical k-root of N (or an integer near N^{1/k}) for k-dimensional clock gating.

Write address bus bits may be partitioned into k disjoint non-empty sets of the write address bus bits for k-dimensional clock gating and address decoding. For two-dimensional clock-gating and address-decoding, the address bus bits may be partitioned into two halves. For example, referring back to FIG. 3, the mid pre-decoder 324 may use upper-half address bits of the write address 306 to enable a mediate ICG cell, and the low pre-decoder 310 may use lower-half address bits of the write address 306 to enable a leaf ICG cell in each subset of the leaf ICG cells. The clock signal (CLK) may be blocked for a memory cell row anywhere in the ICG clock tree hierarch, first by an upstream mediate ICG cell and then by a leaf ICG cell. The mid-predecoder 324 and the low pre-decoder 310 become smaller in this way, and the latter may be shared among the subsets of the leaf ICG cells, helping to reduce routing congestion. An example of HDL code for such an RTL memory is:

```
parameter CLOG2_DEGREE_ICG = WRADDR_WIDTH−WRADDR_WIDTH/2
localparam NUM_MICG = 2 ** (WRADDR_WIDTH − CLOG2_DEGREE_ICG);
wire [NUM_MICG−1:0] clk_gated ;
wire [(2**CLOG2_DEGREE_ICG)−1:0] wrSel_post ;
genvar micg_t1 ;
generate
  for (micg_t1=0; micg_t1<NUM_MICG; micg_t1++) begin:u_micg_t1
  ‘POS_EDGE_ICG(u_micg, clk_gated[icg_t1], WrEn &&
(WrAddr[WRADDR_WIDTH−1: CLOG2_DEGREE_ICG]==icg_t1), 1′b0, clk)
  end
endgenerate
genvar post_t2 ;
generate
  for (post_t2=0; post_t2<(2**CLOG2_DEGREE_ICG); post_t2++) begin:u_post_t2
    assign wrSel_post[post_t2] = (WrAddr[CLOG2_DEGREE_ICG−1:0]==post_t2);
  end
endgenerate
genvar mem_t1 ;
generate
for (micg_t1=0; micg_t1<NUM_MICG; micg_t1++) begin
  for (mem_t1=micg_t1*(2**CLOG2_DEGREE_ICG);
mem_t1<(micg_t1+1)*(2**CLOG2_DEGREE_ICG); mem_t1++) begin
    if (mem_t1 < NUM_EMTRIES) begin
      always @ (posedge clk_gated[micg_t1]) begin
        if (wrSel_post[mem_t1%(2**CLOG2_DEGREE_ICG)]) begin
          Mem[mem_t1] <= WrData;
        end
      end
    end
  end
end
endgenerate
```

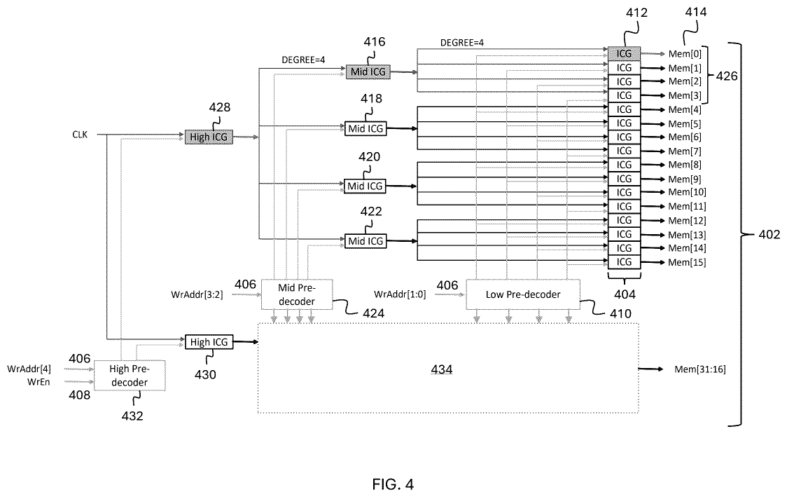

FIG. 4 is a diagram illustrating three-dimensional clock gating by an RTL memory, according to an embodiment. Similar to FIGS. 2 and 3, a leaf ICG cell is disposed at each memory cell row and may be enabled by a write address decoder. As an alternative, instead of leaf ICG cells, the rows of memory cells may embed a multiplexer in each memory cell. FIG. 4 illustrates an example with 32 rows of memory cells (i.e., Mem[0-31]) 402. The rows of memory cells 402 may have respective leaf ICG cells 404. Similar to FIG. 3, mediate ICG (mid ICG) cells may be provided for subsets of the ICG leaf cells 404. Specifically, a first mediate ICG cell 416 may be provided for a first subset of the leaf ICG cells 404 corresponding to a first group of four memory cell rows Mem[0-3] 426. A second mediate ICG cell 418 may be provided for a second subset of the leaf ICG cells 404 corresponding to a second group of four memory cell rows Mem[4-7]. A third mediate ICG cell 420 may be provided for a third subset of the leaf ICG cells 404 corresponding to a third group of four memory cell rows Mem[8-11]. A fourth mediate ICG cell 422 may be provided for a fourth subset of the leaf ICG cells 404 corresponding to a fourth group of four memory cell rows Mem[12-15]. Similarly, fifth through eighth mediate ICG cells may be provided for additional subsets of the leaf ICG cells 404 corresponding to groups of memory cell rows in Mem[16-31]. While the upper half of the system is shown for the first 16 rows of memory cells and the first four mediate ICG cells, identical lower half 434 may be provided for the second 16 rows of memory cells and the second four mediate ICG cells.

Higher mediate (high-ICG of secondary mediate ICG) cells may be provided for subsets of the mediate ICG cells. Specifically, a first higher mediate ICG cell 428 may be provided for a first subset of the mediate ICG cells that includes the first mediate ICG cell 416, the second mediate ICG cell 418, the third mediate ICG cell 420, and the fourth mediate ICG cell 422. A second higher mediate ICG cell 430 may be provided for a second subset of the mediate ICG cells that includes the fifth through eighth mediate ICG cells in the lower half 434.

Clock data or a clock signal (CLK) may be provided to each of the first and second higher mediate ICG cells 428 and 430. A write address 406 and a write enable signal 408 may be provided to a high pre-decoder 432. The high pre-decoder 432 may determine which higher mediate ICG cell to activate based on the write address 406 when the write enable signal is asserted. For example, if the write address 406 corresponds to a first memory cell row Mem[0] 414, the first higher mediate ICG cell 428 may generate a gated clock signal for the first sub-set of mediate ICG cells (e.g., the first mediate ICG cell 416, the second mediate ICG cell 418, the third mediate ICG cell 420, and the fourth mediate ICG cell 422). The second higher mediate ICG cell 428 may remain disabled.

The write address 406 may be provided to a mid pre-decoder 424. The mid pre-decoder 424 may determine which mediate ICG cell among the first subset of mediate ICG cells to activate based on the write address 406. For example, if the write address 406 corresponds to the first memory cell row Mem[0] 414, the first mediate ICG cell 416 may generate a gated clock signal for the first subset of the leaf ICG cells 404 corresponding to a first group of four memory cell rows Mem[0-3] 426. The remaining first subset mediate ICG cells 418, 420, and 422 that are not selected by the write address 406 may remain disabled. The mid pre-decoder 424 may also determine which mediate ICG cell among the second subset of mediate ICG cells to activate based on the write address 406.

The write address 406 may also be provided to a low pre-decoder 410. The low pre-decoder 410 may determine which leaf ICG cell among a subset of leaf ICG cells to activate based on the write address 406. For example, if the write address 406 corresponds to the first memory cell row Mem[0] 414, a first leaf ICG cell 412 among the first subset of leaf ICG cells generates a gated clock signal for the first memory cell row 414. The remaining three first subset leaf ICG cells that are not selected by the write address 406 may remain disabled. The low pre-decoder 410 may also be used for the remaining subsets of leaf ICG cells to determine which leaf ICG cell to activate among each subset of leaf ICG cells.

This selective activation may conserve power by limiting output clock activity to the first higher mediate ICG cell 428, the first mediate ICG cell 416, and the first leaf ICG cell 412. The input clock power for inactive ICG cells is limited to the second higher mediate ICG cell 430, the second mediate ICG cell 418, the third mediate ICG cell 420, the fourth mediate ICG cell 422, and the remaining three leaf ICG cells in the first subset of the leaf ICG cells 404. An input clock power is not provided to the second set of mediate ICG cells and the second through eighth subsets of the leaf ICG cells 404. While FIG. 4 is shown with 32 leaf ICG cells, eight mediate ICG cells, and two higher mediate ICG cells, embodiments are not limited to such a configuration.

Accordingly, multi-dimensional clock gating with corresponding address decoding may be provided for an active memory where dynamic power saving out-weighs area cost and leakage power increase.

Various aspect may be automated in an RTL HDL compiler, enhancing current single-level ICGs for fine-grain clock gating to multi-dimensional clock gating and associated address decoding for optimum power, performance, and area (PPA).

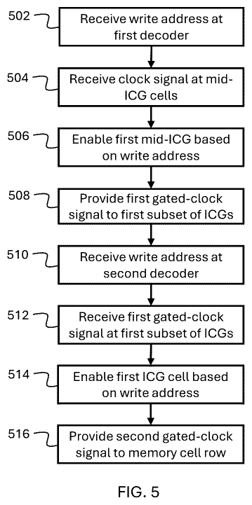

FIG. 5 is a flowchart illustrating a clock-gating method for a memory device, according to an embodiment. At 502, at least a first portion of a write address bus with a write address from a write command may be received at a first decoder of the memory device. At 504, a clock signal may be received at mediate ICG cells of the memory device. The mediate ICG cells correspond to respective subsets of memory cell rows of the memory device. The number of mediate ICG cells may be a floor or a ceiling of a square-root of the number of memory cell rows. Alternatively, the number of mediate ICG cells may be a ceiling of (n/2^{m}), where n is the number of memory cell rows and m is one of two integers closest to half of a bus size of the write address bus.

At 506, the first decoder may enable a first mediate ICG cell among the mediate ICG cells based on the first portion of the write address bus with the write address. The first mediate ICG cell corresponds to a first subset of the memory cell rows having a memory cell row for the write address. The first decoder may disable remaining mediate ICG cells among the mediate ICG cells.

At 508, the first mediate ICG cell may provide a first gated clock signal from the clock signal to a first subset of leaf ICG cells corresponding to the first subset of the memory cell rows, or directly to the first subset of the multiplexer-embedded memory cell rows. The disabled remaining mediate ICG cells may block further provision of the clock signal (i.e., provide first blocked clock signals) to the remaining leaf ICG cells or multiplexer-embedded memory cell rows corresponding to the remaining subsets of the memory cell rows.

At 510, a second portion of the write address bus with the write address may be received at a second decoder of the memory device. The first portion of the write address bus may include upper address bits of the write address, and the second portion of the write address bus may include lower address bits of the write address.

At 512, the first subset of leaf ICG cells or memory cell rows with embedded multiplexers corresponding to the first subset of the memory cell rows may receive the first gated clock signal from the first mediate ICG cell. The remaining leaf ICG cells or multiplexer-embedded memory cell rows corresponding to the remaining subsets of the memory cell rows may receive the first blocked clock signals from the corresponding mediate ICG cells.

At 514, the second decoder may enable a first leaf ICG cell among the first subset of leaf ICG cells or let a first embedded multiplexer row corresponding to a first memory cell row among the first subset of the memory cell rows select input data, based on the write address. The first leaf ICG cell or the first embedded multiplexer row may correspond to the memory cell row for the write address. The second decoder may disable remaining leaf ICG cells among the first subset of leaf ICG cells or let the remaining embedded multiplexer rows corresponding to the remaining memory cell rows of the first subset of memory cell rows select their own respective memory cell values.

At 516, the first leaf ICG cell among the first subset of leaf ICG cells may provide a second gated clock signal from the first gated clock signal to memory cells in the first memory cell row, or the memory cells with embedded multiplexers corresponding to the first memory cell row among the first subset of the memory cell rows may receive the first gated clock signal with the multiplexers selecting input data. The remaining leaf ICG cells among the first subset of leaf ICG cells may provide second blocked clock signals to the corresponding memory cell rows, or the memory cells with embedded multiplexers corresponding to the remaining memory cell rows among the first subset of the memory cell rows may receive the first gated clock signal with the multiplexers selecting their own respective memory cell values. The remaining leaf ICG cells among the remaining subsets of leaf ICG cells may provide other second blocked clock signals to the corresponding memory cell rows, or the memory cells with embedded multiplexers corresponding to the memory cell rows among the remaining subsets of the memory cell rows may receive corresponding first block clock signals.

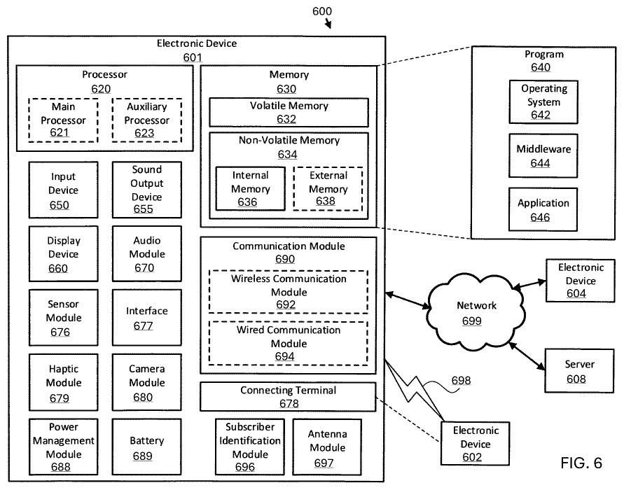

FIG. 6 is a block diagram of an electronic device in a network environment 600, according to an embodiment.

Referring to FIG. 6, an electronic device (or UE) 601 in a network environment 600 may communicate with an electronic device 602 via a first network 698 (e.g., a short-range wireless communication network), or an electronic device 604 or a server 608 via a second network 699 (e.g., a long-range wireless communication network). The electronic device 601 may communicate with the electronic device 604 via the server 608. The electronic device 601 may include a processor 620, a memory 630, an input device 650, a sound output device 655, a display device 660, an audio module 670, a sensor module 676, an interface 677, a haptic module 679, a camera module 680, a power management module 688, a battery 689, a communication module 690, a subscriber identification module (SIM) card 696, or an antenna module 697. In one embodiment, at least one (e.g., the display device 660 or the camera module 680) of the components may be omitted from the electronic device 601, or one or more other components may be added to the electronic device 601. Some of the components may be implemented as a single integrated circuit (IC). For example, the sensor module 676 (e.g., a fingerprint sensor, an iris sensor, or an illuminance sensor) may be embedded in the display device 660 (e.g., a display).

The processor 620 may execute software (e.g., a program 640) to control at least one other component (e.g., a hardware or a software component) of the electronic device 601 coupled with the processor 620 and may perform various data processing or computations.

As at least part of the data processing or computations, the processor 620 may load a command or data received from another component (e.g., the sensor module 676 or the communication module 690) in volatile memory 632, process the command or the data stored in the volatile memory 632, and store resulting data in non-volatile memory 634. The processor 620 may include a main processor 621 (e.g., a CPU or an application processor (AP)), and an auxiliary processor 623 (e.g., a GPU, an image signal processor (ISP), a sensor hub processor, or a communication processor (CP)) that is operable independently from, or in conjunction with, the main processor 621. Additionally or alternatively, the auxiliary processor 623 may be adapted to consume less power than the main processor 621, or execute a particular function. The auxiliary processor 623 may be implemented as being separate from, or a part of, the main processor 621.

The auxiliary processor 623 may control at least some of the functions or states related to at least one component (e.g., the display device 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). The auxiliary processor 623 (e.g., an image signal processor or a communication processor) may be implemented as part of another component (e.g., the camera module 680 or the communication module 690) functionally related to the auxiliary processor 623.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634. Non-volatile memory 634 may include internal memory 636 and/or external memory 638.

The program 640 may be stored in the memory 630 as software, and may include, for example, an operating system (OS) 642, middleware 644, or an application 646.

The input device 650 may receive a command or data to be used by another component (e.g., the processor 620) of the electronic device 601, from the outside (e.g., a user) of the electronic device 601. The input device 650 may include, for example, a microphone, a mouse, or a keyboard.

The sound output device 655 may output sound signals to the outside of the electronic device 601. The sound output device 655 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 660 may visually provide information to the outside (e.g., a user) of the electronic device 601. The display device 660 may include, for example, a display, a hologram device, or a projector and control circuitry to control a corresponding one of the display, hologram device, and projector. The display device 660 may include touch circuitry adapted to detect a touch, or sensor circuitry (e.g., a pressure sensor) adapted to measure the intensity of force incurred by the touch.

The audio module 670 may convert a sound into an electrical signal and vice versa. The audio module 670 may obtain the sound via the input device 650 or output the sound via the sound output device 655 or a headphone of an external electronic device 602 directly (e.g., wired) or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device 602 directly (e.g., wired) or wirelessly. The interface 677 may include, for example, a high-definition multimedia interface (HDMI), a universal serial bus (USB) interface, a secure digital (SD) card interface, or an audio interface.

A connecting terminal 678 may include a connector via which the electronic device 601 may be physically connected with the external electronic device 602. The connecting terminal 678 may include, for example, an HDMI connector, a USB connector, an SD card connector, or an audio connector (e.g., a headphone connector).

The haptic module 679 may convert an electrical signal into a mechanical stimulus (e.g., a vibration or a movement) or an electrical stimulus which may be recognized by a user via tactile sensation or kinesthetic sensation. The haptic module 679 may include, for example, a motor, a piezoelectric element, or an electrical stimulator.

The camera module 680 may capture a still image or moving images. The camera module 680 may include one or more lenses, image sensors, image signal processors, or flashes. The power management module 688 may manage power supplied to the electronic device 601. The power management module 688 may be implemented as at least part of, for example, a power management integrated circuit (PMIC).

The battery 689 may supply power to at least one component of the electronic device 601. The battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the AP) and supports a direct (e.g., wired) communication or a wireless communication. The communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as BLUETOOTH™, wireless-fidelity (Wi-Fi) direct, or a standard of the Infrared Data Association (IrDA)) or the second network 699 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The antenna module 697 may transmit or receive a signal or power to or from the outside (e.g., the external electronic device) of the electronic device 601. The antenna module 697 may include one or more antennas, and, therefrom, at least one antenna appropriate for a communication scheme used in the communication network, such as the first network 698 or the second network 699, may be selected, for example, by the communication module 690 (e.g., the wireless communication module 692). The signal or the power may then be transmitted or received between the communication module 690 and the external electronic device via the selected at least one antenna.

Commands or data may be transmitted or received between the electronic device 601 and the external electronic device 604 via the server 608 coupled with the second network 699. Each of the electronic devices 602 and 604 may be a device of a same type as, or a different type, from the electronic device 601. All or some of operations to be executed at the electronic device 601 may be executed at one or more of the external electronic devices 602, 604, or 608. For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 601. The electronic device 601 may provide the outcome, with or without further processing of the outcome, as at least part of a reply to the request. To that end, a cloud computing, distributed computing, or client-server computing technology may be used, for example.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method comprising:
receiving at least a first portion of a write address bus comprising a write address from a write command at a first decoder of a memory device, wherein the memory device comprises a set of memory cell rows corresponding to a subset of write addresses from write commands;
receiving a first clock signal at a first primary integrated clock gating (ICG) cell of the memory device, wherein the first primary ICG cell is configured to provide a first gated clock signal to a first subcircuit of the memory device comprising a first non-empty proper subset of the memory cell rows, wherein the first non-empty proper subset comprises a plurality of memory cell rows; and
enabling or disabling, by the first decoder, when the write address is in the subset of the write addresses, the first primary ICG cell, based on whether the write address corresponds to any memory cell row in the first non-empty proper subset of the memory cell rows, disabling the first primary ICG cell when the write address corresponds to a memory cell row in the set of the memory cell rows but not in the first non-empty proper subset.

2. The method of claim 1, further comprising:
receiving at least a second portion of the write address bus at a second decoder of the memory device;
receiving the first gated clock signal at a first memory cell row of the first non-empty proper subset in the first subcircuit, wherein the first subcircuit further comprises an embedded multiplexer row in the first memory cell row; and
configuring, by the second decoder, when the write address corresponds to any memory cell row in the first non-empty proper subset, the embedded multiplexer row to feed memory data input to the first memory cell row or to self-feed the first memory cell row with its own stored value, based on whether the write address corresponds to the first memory cell row in the first non-empty proper subset of the memory cell rows, self-feeding the first memory cell row when the write address corresponds to any memory cell row in the first non-empty proper subset of the memory cell rows other than the first memory cell row.

3. The method of claim 1, further comprising:
receiving at least a second portion of the write address bus at a second decoder of the memory device;
receiving the first gated clock signal at a first leaf ICG cell in the first subcircuit, wherein the first leaf ICG cell is configured to provide a first leaf gated clock signal to a first memory cell row of the first non-empty proper subset of the memory cell rows; and
enabling or disabling, by the second decoder, when the write address corresponds to any memory cell row in the first non-empty proper subset, the first leaf ICG cell, based on whether the write address corresponds to the first memory cell row in the first non-empty proper subset of the memory cell rows, disabling the first leaf ICG cell when the write address corresponds to any memory cell row in the first non-empty proper subset of the memory cell rows other than the first memory cell row.

4. The method of claim 1, further comprising:
receiving at least a second portion of the write address bus at a second decoder of the memory device;
receiving the first gated clock signal at a first secondary ICG cell in the first subcircuit of the memory device, wherein the first secondary ICG cell is configured to provide a first secondary gated clock signal to a first nested subcircuit in the first subcircuit, and wherein the first nested subcircuit comprises a first secondary non-empty subset of the first non-empty proper subset of the memory cell rows; and
enabling or disabling, by the second decoder, when the write address corresponds to any memory cell row in the first non-empty proper subset, the first secondary ICG cell, based on whether the write address corresponds to any memory cell row in the first secondary non-empty subset of the memory cell rows, disabling the first secondary ICG cell when the write address corresponds to a memory cell row in the first non-empty proper subset but not in the first secondary non-empty subset.

5. The method of claim 3, wherein the cardinality of the first non-empty proper subset of the memory cell rows is:
a floor of a square-root of the cardinality of the set of the memory cell rows; or
a ceiling of the square-root of the cardinality of the set of the memory cell rows.

6. The method of claim 4, wherein the first portion of the write address bus comprises upper address bits, excluding a least significant bit (LSB), of the write address bus, and the cardinality of the first non-empty proper subset of the memory cell rows is two to the power of the number of the remaining lower address bits of the write address bus.

7. The method of claim 6, wherein the number of the remaining lower address bits is a floor or a ceiling of one-half of a size of the write address bus.

8. The method of claim 1, further comprising:
receiving a write enable signal at the first decoder, and
disabling the first primary ICG cell when the write enable signal is de-asserted.

9. The method of claim 1, further comprising:
receiving the first clock signal at a second primary ICG cell of the memory device, wherein the second primary ICG cell is configured to provide a second gated clock signal to a second subcircuit of the memory device comprising a second non-empty subset of the memory cell rows that is disjoint with the first non-empty proper subset; and
enabling or disabling, by the first decoder, when the write address is in the subset of the write addresses, the second primary ICG cell, based on whether the write address corresponds to any memory cell row in the second non-empty subset of the memory cell rows, disabling the second primary ICG cell when the write address corresponds to a memory cell row in the set of the memory cell rows but not in the second non-empty subset.

10. The method of claim 6, wherein the second portion of the write address bus is non-overlapping with the first portion of the write address bus, further comprising:
receiving the first clock signal at a second primary ICG cell of the memory device, wherein the second primary ICG cell is configured to provide a second gated clock signal to a second subcircuit of the memory device comprising a second non-empty subset of the memory cell rows that is disjoint with the first non-empty proper subset;
enabling or disabling, by the first decoder, when the write address is in the subset of the write addresses, the second primary ICG cell, based on whether the write address corresponds to any memory cell row in the second non-empty subset of the memory cell rows, disabling the second primary ICG cell when the write address corresponds to a memory cell row in the set of the memory cell rows but not in the second non-empty subset;
receiving the second gated clock signal at a second secondary ICG cell in the second subcircuit of the memory device, wherein the second secondary ICG cell is configured to provide a second secondary gated clock signal to a second nested subcircuit in the second subcircuit, and wherein the second nested subcircuit comprises a second secondary non-empty subset of the second non-empty subset of the memory cell rows; and
enabling or disabling, by the second decoder, when the write address corresponds to any memory cell row in the second non-empty subset, the second secondary ICG cell, based on whether the write address corresponds to any memory cell row in the second secondary non-empty subset of the memory cell rows, disabling the second secondary ICG cell when the write address corresponds to a memory cell row in the second non-empty subset but not in the second secondary non-empty subset.

11. The method of claim 4, further comprising:
receiving at least a third portion of the write address bus at a third decoder of the memory device;
receiving the first secondary gated clock signal at a first tertiary ICG cell in the first nested subcircuit of the memory device, wherein the first tertiary ICG cell is configured to provide a first tertiary gated clock signal to a first double-nested subcircuit in the first nested subcircuit, and wherein the first double-nested subcircuit comprises a first tertiary non-empty subset of the first secondary non-empty subset of the memory cell rows; and
enabling or disabling, by the third decoder, when the write address corresponds to any memory cell row in the first secondary non-empty subset, the first tertiary ICG cell, based on whether the write address corresponds to any memory cell row in the first tertiary non-empty subset of the memory cell rows, disabling the first tertiary ICG cell when the write address corresponds to a memory cell row in the first secondary non-empty subset but not in the first tertiary non-empty subset.

12. A memory device comprising:
a write address bus configured to receive a write address from a write command;
a set of memory cell rows corresponding to a subset of write addresses from write commands;
a first subcircuit comprising a first non-empty proper subset of the memory cell rows, wherein the first non-empty proper subset comprises a plurality of memory cell rows;
a first primary integrated clock gating (ICG) cell configured to receive a first clock signal and provide a first gated clock signal to the first subcircuit; and
a first decoder configured to receive at least a first portion of the write address bus and to enable or disable the first primary ICG cell, when the write address is in the subset of the write addresses, based on whether the write address corresponds to any memory cell row in the first non-empty proper subset of the memory cell rows, disabling the first primary ICG cell when the write address corresponds to a memory cell row in the set of the memory cell rows but not in the first non-empty proper subset.

13. The memory device of claim 12, wherein the first subcircuit is configured to receive the first gated clock signal at a first memory cell row of the first non-empty proper subset in the first subcircuit, wherein the first subcircuit further comprises an embedded multiplexer row in the first memory cell row of the first non-empty proper subset of the memory cell rows, and further comprising:
a second decoder, configured to receive at least a second portion of the write address bus, configuring, when the write address corresponds to any memory cell row in the first non-empty proper subset, the embedded multiplexer row to feed memory data input to the first memory cell row or to self-feed the first memory cell row with its own stored value, based on whether the write address corresponds to the first memory cell row, self-feeding the first memory cell row when the write address corresponds to any memory cell row in the first non-empty proper subset of the memory cell rows other than the first memory cell row.

14. The memory device of claim 12, wherein the first subcircuit further comprises a first leaf ICG cell configured to receive the first gated clock signal and provide a first leaf gated clock signal to a first memory cell row of the first non-empty proper subset of memory cell rows, further comprising:
a second decoder configured to receive at least a second portion of the write address bus, and to enable or disable the first leaf ICG cell, when the write address corresponds to any memory cell row in the first non-empty proper subset, based on whether the write address corresponds to the first memory cell row, disabling the first leaf ICG cell when the write address corresponds to any memory cell row in the first non-empty proper subset of the memory cell rows other than the first memory cell row.

15. The memory device of claim 12, wherein the first subcircuit further comprises a first secondary ICG cell and a first nested subcircuit comprising a first secondary non-empty subset of the first non-empty proper subset, the first secondary ICG cell being configured to receive the first gated clock signal and provide a first secondary gated clock signal to the first nested subcircuit, further comprising:
a second decoder configured to receive at least a second portion of the write address bus, and to enable or disable the first secondary ICG cell, when the write address corresponds to any memory cell row in the first non-empty proper subset, based on whether the write address corresponds to any memory cell row in the first secondary non-empty subset of the memory cell rows, disabling the first secondary ICG cell when the write address corresponds to a memory cell row in the first non-empty proper subset but not in the first secondary non-empty subset.

16. The memory device of claim 12, wherein the first decoder is further configured to receive a write enable signal and to disable the first primary ICG cell when the write enable signal is de-asserted.

17. The memory device of claim 12, further comprising:
a second subcircuit comprising a second non-empty subset of memory cell rows that is disjoint with the first non-empty proper subset; and
a second primary ICG cell configured to receive the first clock signal and provide a second gated clock signal to the second subcircuit,
wherein the first decoder is configured to enable or disable the second primary ICG cell, when the write address is in the subset of the write addresses, based on whether the write address corresponds to any memory cell row in the second non-empty subset of the memory cell rows, disabling the second primary ICG cell when the write address corresponds to a memory cell row in the set of the memory cell rows but not in the second non-empty subset.

18. The memory device of claim 15, wherein the second portion of the write address bus is non-overlapping with the first portion of the write address bus, further comprising:
a second subcircuit comprising a second secondary ICG cell and a second non-empty subset of memory cell rows that is disjoint with the first non-empty proper subset;
a second primary ICG cell configured to receive the first clock signal and to provide a second gated clock signal to the second subcircuit,
wherein the second primary ICG cell is further configured to be enabled or disabled, by the first decoder, when the write address is in the subset of the write addresses, based on whether the write address corresponds to any memory cell row in the second non-empty subset of the memory cell rows, disabled when the write address corresponds to a memory cell row in the set of the memory cell rows but not in the second non-empty subset, and wherein
the second secondary ICG cell is configured to receive the second gated clock signal and to provide a second secondary gated clock signal to the second nested subcircuit, and it is further configured to be enabled or disabled, by the second decoder, when the write address corresponds to any memory cell row in the second non-empty subset, based on whether the write address corresponds to any memory cell row in the second secondary non-empty subset of the memory cell rows, disabled when the write address corresponds to a memory cell row in the second non-empty subset but not in the second secondary non-empty subset.

19. The memory device of claim 15, further comprising a third decoder configured to receive at least a third portion of the write address bus, wherein the first nested subcircuit further comprises a first tertiary ICG cell and a first double-nested subcircuit comprising a first tertiary non-empty subset of the first secondary non-empty subset of the memory cell rows, and wherein
the first tertiary ICG cell is configured to receive the first secondary gated clock signal and to provide a first tertiary gated clock signal to the first double-nested subcircuit, and it is further configured to be enabled or disabled, by the third decoder, when the write address corresponds to any memory cell row in the first secondary non-empty subset, based on whether the write address corresponds to any memory cell row in the first tertiary non-empty subset of the memory cell rows, disabled when the write address corresponds to a memory cell row in the first secondary non-empty subset but not in the first tertiary non-empty subset.

20. An electronic device comprising:
a processor; and
a non-transitory computer readable storage medium storing instructions that, when executed, cause the processor to:
receive at least a first portion of a write address bus comprising a write address from a write command at a first decoder of a memory device, wherein the memory device comprises a set of memory cell rows corresponding to a subset of write addresses from write commands;
receive a first clock signal at a first primary integrated clock gating (ICG) cell of the memory device, wherein the first primary ICG cell is configured to provide a first gated clock signal to a first subcircuit of the memory device comprising a first non-empty proper subset of the memory cell rows, wherein the first non-empty proper subset comprises a plurality of memory cell rows; and
enable or disable the first primary ICG cell, when the write address is in the subset of the write addresses, based on whether the write address corresponds to any memory cell row in the first non-empty proper subset of the memory cell rows, disabling the first primary ICG cell when the write address corresponds to a memory cell row in the set of the memory cell rows but not in the first non-empty proper subset.
